(19) United States
(12) Patent Application Publication
(10) Pub. No.: US 2026/0110711 A1
(43) Pub. Date: Apr. 23, 2026

(54) TESTING METHOD, PROBE HEAD, PROBE CARD AND PROBE SYSTEM FOR MICRO-BUMP TEST AND TESTED DEVICE

(71) Applicant: MPI CORPORATION, CHU-PEI CITY (TW)

(72) Inventor: CHIN-TIEN YANG, CHU-PEI CITY (TW)

(73) Assignee: MPI CORPORATION, CHU-PEI CITY (TW)

(21) Appl. No.: 19/355,548

(22) Filed: Oct. 10, 2025

Related U.S. Application Data
(60) Provisional application No. 63/708,408, filed on Oct. 17, 2024.

(30) Foreign Application Priority Data
Jul. 17, 2025 (TW) 114127111

(51) Int. Cl. G01R 1/073

(52) U.S. Cl. CPC G01R 1/07342

(57) ABSTRACT

The present invention provides a testing method, a probe head, a probe card and a probe system for a micro-bump test. The testing method includes providing a DUT with first and second bump units for transmitting power or ground signal and test signal, respectively, wherein the first bump unit has micro-bumps grouping together; placing the DUT on a chuck; providing the probe card wherein the interval between the head portions of the adjacent probes is larger than or equal to the width of one micro-bump; and testing the DUT by using the head portions of the probes to contact the bump units of the DUT, respectively. That lowers the manufacturing difficulty and cost of the probe card, and the difficulty of using it on the machine for testing, prevents the DUT from too complicated design, and prevents the adjacent probes from collision and the resulting short circuit or interference.

### BACKGROUND OF THE INVENTION

### 1. Field of the Invention

The present invention relates generally to micro-bump testing technology and more particularly, to a testing method, a probe head, a probe card and a probe system for a micro-bump test, and a tested device.

### 2. Description of the Related Art

As the development of system in package technology trends more and more important, 2.5D/3D stacking package technology receives more and more attention in the electronic product market. Wherein, chiplets or interposers adopt micro-bumps for 2.5D/3D stacking package, so the need to testing micro-bumps trends upwards.

Each device under test (also referred to as DUT hereinafter) has many micro-bumps. The amount may be more than 100 thousand. Besides, the micro-bumps have very small size (about 10-30 μm in diameter) and pitch (about 25-60 μm). If the test is performed by directly using probes of a probe card to contact the micro-bumps, the probes of the probe card need sufficient intervals therebetween for mechanical operation. Therefore, the probe card will be very difficult in manufacture and very expensive, and also difficult in practical use on a machine for testing.

The testing manner using sacrificial pads (or called schemed pads) is mainly adopted in the industry presently, wherein additional pads with relatively larger pitch, e.g. 100-180 μm, are provided for being electrically contacted by the probes. However, this testing manner not only wastes the useful area on dies, but also unfavorably affects high-frequency/high-speed tests.

In the industry, it is also tried to design additional sacrificial bumps (or called schemed bumps) for being electrically contacted by the probes, wherein bumps with relatively larger size and pitch are used for lowering the difficulty of manufacturing the probe card and using the probe card on the machine for testing. However, this manner also wastes the useful area on dies, and the design is limited by trace space and amount.

Another testing manner called selected bump is also tried in the industry, wherein only some micro-bumps are chosen to be tested, but not all the micro-bumps are tested. In this testing manner, although the probe card can have relatively larger pitch between the probes, but it still tests the bumps with very small size, thereby having certain difficulty. Besides, this testing manner will cause further complication to the design of the device under test, so it is hard to be adopted comprehensively.

### SUMMARY OF THE INVENTION

The micro-bumps in each device under test are mostly power micro-bumps for transmitting the power signal and ground micro-bumps for transmitting the ground signal. Therefore, the testing manner of using a single probe to contact a plurality of power micro-bumps and/or ground micro-bumps can be adopted, such that the amount of the probes of the probe card is highly reduced and thereby the cost of the probe card is lowered. However, there may be still a problem of insufficient interval between the probes. That is, in the condition that the interval between the probes is too small, the adjacent probes may partially contact each other to result in short circuit or interference problem. For example, the tail portion of the probe usually has a stopping part. The width of the stopping part is larger than the width of the guiding hole of the guide plate the tail portion is inserted through, so that the relative position between the probe and the guide plate is limited and thereby the probe is prevented from falling down. Therefore, the stopping parts of the probes have larger width than other sections of the probes, prone to collide with each other to cause the short circuit or interference problem.

The present invention has been accomplished in view of the above-noted circumstances. It is an objective of the present invention to provide a testing method, a probe head, a probe card and a probe system for a micro-bump test, which can lower the difficulty of manufacturing the probe card, the cost of the probe card and the difficulty of using the probe card on the machine for testing, and can prevent the device under test from too complicated design, and can prevent the adjacent probes from collision with each other and the resulting short circuit or interference problem.

To attain the above objective, the present invention provides a testing method for a micro-bump test, which uses a probe card in a probe system to test a device under test having a plurality of micro-bumps. The testing method includes the steps of:
providing the device under test, the device under test including a plurality of bump units, the plurality of bump units including at least one first bump unit and at least one second bump unit, the first bump unit including a plurality of micro-bumps grouping together, the micro-bumps of the same first bump unit being all arranged for transmitting a first signal, the first signal being one of a power signal and a ground signal, the second bump unit being arranged for transmitting a second signal, the second signal being a test signal different from the power signal and the ground signal;
placing the device under test on a chuck of the probe system;
providing the probe card, the probe card including a plurality of probes, each of the probes including a head portion located at an end of the probe for contacting the device under test, a tail portion located at the other end of the probe, and a body portion located between the head portion and the tail portion, the interval between the head portions of at least two adjacent probes being larger than or equal to the width of one micro-bump; and
testing the device under test by using the head portions of the probes of the probe card to contact the bump units of the device under test respectively.

As a result, the plurality of probes of the probe card are arranged for contacting the plurality of bump units of the device under test respectively. That is, each probe contacts only one bump unit, and each bump unit is contacted by only one probe. In other words, the plurality of micro-bumps of the first bump unit are contacted by a single probe in common, so that the single probe transmits the power signal or the ground signal to the plurality of micro-bumps of the first bump unit at the same time. Further speaking, on the device under test, the power micro-bumps for transmitting the power signal and the ground micro-bumps for transmitting the ground signal can be arranged according to the above-described arrangement of the first bump unit. That is, a plurality of power micro-bumps or ground micro-bumps group together into a first bump unit. Therefore, a large number of power micro-bumps and ground micro-bumps on the device under test are arranged into a plurality of first bump units, such that a much smaller number of probes than the power micro-bumps and the ground micro-bumps can be utilized to contact the power micro-bumps and the ground micro-bumps. In this way, the probe card can be arranged with relatively fewer probes, and the probes can be provided therebetween with relatively larger pitch, wherein most probes or all probes are arranged to contact a plurality of micro-bumps. Therefore, the difficulty of manufacturing the probe card, the cost of the probe card and the difficulty of using and maintaining the probe card are relatively lower, and the design of the device under test is not too complicated. In addition, the interval between the head portions of at least two adjacent probes, or every two adjacent probes, is larger than or equal to the width of one micro-bump, such that the adjacent probes have a relatively larger interval therebetween for mechanical operation. That prevents the adjacent probes from collision with each other and the resulting short circuit or interference problem, so as to satisfy the testability and the reliability, improve the stability and test accuracy of the testing process, and improve the MTBF (mean time between failures) and service life of the probe card.

The probe head for the micro-bump test provided by the present invention is included in a probe card for testing a device under test having a plurality of micro-bumps. The probe head includes a guide unit including a plurality of guiding holes, and a plurality of probes inserted through the plurality of guiding holes respectively. Each of the probes includes a head portion located at an end of the probe for contacting the device under test, a tail portion located at the other end of the probe, and a body portion located between the head portion and the tail portion. The head portions of the plurality of probes are arranged for contacting a plurality of bump units of the device under test respectively. The plurality of bump units include at least one first bump unit and at least one second bump unit. The first bump unit includes a plurality of micro-bumps grouping together. The micro-bumps of the same first bump unit are all arranged for transmitting a first signal. The first signal is one of a power signal and a ground signal. The second bump unit is arranged for transmitting a second signal. The second signal is a test signal different from the power signal and the ground signal. The interval between the head portions of at least two adjacent probes is larger than or equal to the width of one micro-bump.

As a result, the probe arrangement of the probe head, and the bump unit arrangement of the device under test which the probe head is arranged to test, are the same with those described in the aforementioned testing method. That can lower the difficulty of manufacturing the probe card, the cost of the probe card, and the difficulty of using the probe card on the machine for testing, and can prevent the device under test from too complicated design and prevent the adjacent probes from collision with each other and the resulting short circuit or interference problem.

Preferably, in the aforementioned testing method and probe head, the second bump unit includes a plurality of micro-bumps grouping together. The amount of the micro-bumps of the second bump unit is the same with the amount of the micro-bumps of the first bump unit. The micro-bumps of the second bump unit include at least one selected micro-bump arranged for transmitting the second signal, and at least one dummy micro-bump unable to transmit the second signal out of the second bump unit.

As a result, except for a large number of power micro-bumps and/or ground micro-bumps, the device under test also has relatively fewer testing micro-bumps for the input and output of test signals, so the testing micro-bumps can be arranged according to the above-described arrangement of the second bump unit. That is, at a place near the testing micro-bump for actually transmitting the test signal, i.e. selected micro-bump, one or more extra micro-bumps, i.e. dummy micro-bumps, may be additionally provided so that they group together into a second bump unit for a same probe to contact a plurality of micro-bumps of a same second bump unit at the same time, including the selected micro-bump and the dummy micro-bump, so as to provide the test signal to the circuit corresponding to the selected micro-bump. In other words, the probe contacting the first bump unit and the probe contacting the second bump unit contact the same number of micro-bumps, so they can be the probes of the same size. The dummy micro-bump bears a part of the probe contact force to make the probing pressure received by the selected micro-bump the same with the probing pressure received by the micro-bump of the first bump unit. Although it is described above that the micro-bumps receive the same probing pressure, it can be also understood by those skilled in this technical field as the probes apply the same contact force to the micro-bumps.

Further speaking, the present invention can still use a single probe to contact a single testing micro-bump, such that an arrangement of hybrid probes should be adopted. That is, there are two or more probe types in a same probe card, so that the probe contacting a plurality of power micro-bumps and/or ground micro-bumps generates relatively larger contact force, and the probe contacting a single testing micro-bump generates relatively smaller contact force. However, in the condition that there are at least two different probe types in a same probe card, the probes of different probe types are different in wear loss, so the probe card, after used for a period of time, is prone to the problem of poor probe planarity, which means the terminal ends of the probes are not located on a same horizontal plane. By the above-described arrangement that one or more extra dummy micro-bumps are additionally provided near the selected micro-bump to bear a part of the probe contact force, the present invention can avoid using hybrid probes, so as to avoid the poor probe planarity problem that may be caused by the difference in wear loss between the probes of different probe types, and can also lower the cost of the probe card, the difficulty of manufacturing the probe card, and the difficulty of using and maintaining the probe card.

More preferably, in the aforementioned testing method and probe head, the first bump unit includes two to four micro-bumps grouping together. The second bump unit includes one selected micro-bump and one to three dummy micro-bumps, which group together.

As a result, the first and second bump units both have two to four micro-bumps. Grouping the micro-bumps of such amount together into the bump unit is a relatively easier arrangement. Besides, the probe for contacting the micro-bumps of such amount has a relatively moderate size, which is beneficial for manufacturing and arranging and convenient in use.

Preferably, in the aforementioned testing method and probe head, the body portions of the plurality of probes are substantially the same in size.

As a result, the body portions of the probes being substantially the same in size means the body portions of the probes are substantially the same in structural type, and/or substantially the same in length, width and thickness, and/or substantially the same in cross-sectional area. For example, the body portions of the probes may be substantially the same in all the aspects of structural type, length, width, thickness and cross-sectional area. In this way, the probes will generate substantially the same probe contact force and wear loss. Of course, the probes may not only have the same body portions, but also be substantially the same in size of the head portion and/or the tail portion. However, the head portion and the tail portion have relatively less affection on the probe contact force. In other words, when it is mentioned in the present invention that avoid using hybrid probes to make the probes generate substantially the same probe contact force and wear loss, in a broad sense, to avoid using hybrid probes means all the adopted probes are the same probes, or at least the body portions of all the adopted probes are substantially the same in size. The aforementioned the same probes are entirely, including the head portion, the tail portion and the body portion, substantially the same in structural type, and/or substantially the same in length, width and thickness, and/or substantially the same in cross-sectional area. For example, the probes may be substantially the same in all the aspects of structural type, length, width, thickness and cross-sectional area.

Preferably, in the aforementioned testing method and probe head, the width of each micro-bump is substantially smaller than 30 micrometers. The amount of the probes is at least 10000. The width of the head portion of each probe is substantially smaller than 100 micrometers. The cross-sectional shape of the head portion of each probe is a substantial rectangle.

As a result, such probe arrangement is suitable to test the micro-bumps presently adopted in the 2.5D package, and can avoid the problems of high difficulty of manufacturing the probe card, high cost of the probe card, high difficulty of using the probe card on the machine for testing, and too complicated design of the device under test.

Preferably, in the aforementioned testing method and probe head, at least two adjacent bump units are provided therebetween with at least one micro-bump.

As a result, the device under test can still have a large number of micro-bumps arranged intensively, but a part of the power micro-bumps and/or the ground micro-bumps can be excluded from the bump units. That is, there is at least one micro-bump reserved between the adjacent bump units, not belonging to any bump unit, and not going to be contacted by any probe. In this way, in the condition of maintaining the arrangement of the micro-bumps, the interval between the head portions of the adjacent probes can be still larger than or equal to the width of one micro-bump, so as to prevent the adjacent probes from collision with each other and the resulting short circuit or interference problem.

Preferably, in the aforementioned testing method and probe head, the interval between the head portions of at least two adjacent probes, or every two adjacent probes, is substantially larger than or equal to 20 micrometers.

As a result, such probe arrangement is suitable to test the micro-bumps presently adopted in the 2.5D package, and can avoid the problems of high difficulty of manufacturing the probe card, high cost of the probe card, high difficulty of using the probe card on the machine for testing, and too complicated design of the device under test.

Preferably, in the aforementioned testing method and probe head, the plurality of bump units include a plurality of the aforementioned first bump units and a plurality of the aforementioned second bump units. The plurality of probes include a plurality of first probes and a plurality of second probes. The first probes are arranged for contacting the first bump units respectively. The second probes are arranged for contacting the second bump units respectively. The interval between the head portions of the adjacent first probes is smaller than the width of one micro-bump. The interval between the head portions of the adjacent second probes is larger than or equal to the width of one micro-bump.

In other words, the probes in the present invention can be arranged in a way that the probes for transmitting the power signal and the ground signal, i.e. the first probes, are not spaced from each other for at least the width of one micro-bump, but only the probes for transmitting the test signals, i.e. the second probes, are spaced from each other for at least the width of one micro-bump. Such probe arrangement is suitable to test the micro-bumps presently adopted in the 2.5D package, and can also satisfy the testability and reliability, improve the stability and test accuracy of the testing process, and improve the MTBF and service life of the probe card.

Preferably, in the aforementioned testing method and probe head, the plurality of bump units include a plurality of the aforementioned first bump units and a plurality of the aforementioned second bump units. There is no micro-bump between the adjacent first bump units. There is at least one micro-bump between the adjacent second bump units. Each second bump unit includes at least one micro-bump with an amount smaller than the amount of the micro-bumps of each first bump unit.

In other words, the bump units in the present invention can be arranged in a way that the bump units for transmitting the power signal and the ground signal, i.e. the first bump units, are not provided therebetween with any micro-bump, but only the bump units for transmitting the test signals, i.e. the second bump units, are provided therebetween with at least one micro-bump. Besides, the amount of the micro-bumps of the second bump unit is smaller than the amount of the micro-bumps of the first bump unit, so that the probe corresponding to the second bump unit can be thinner than the probe corresponding to the first bump unit. In this way, the adjacent probes for transmitting the power signal and the ground signal, i.e. the adjacent first probes, can be arranged to contact the adjacent first bump units respectively, but the adjacent probes for transmitting the test signals, i.e. the adjacent second probes, can contact the adjacent second bump units with at least one micro-bump therebetween. Such bump arrangement and its corresponding probe arrangement is suitable to test the micro-bumps presently adopted in the 2.5D package, and can also satisfy the testability and reliability, improve the stability and test accuracy of the testing process, and improve the MTBF and service life of the probe card. In addition, the device under test can still have a large number of micro-bumps arranged intensively, but there is at least one micro-bump reserved between the adjacent second bump units, not belonging to any bump unit, and not going to be contacted by any probe. In this way, in the condition of maintaining the arrangement of the micro-bumps, the interval between the head portions of the adjacent second probes can be still larger than or equal to the width of one micro-bump, so as to prevent the adjacent probes from collision with each other and the resulting short circuit or interference problem.

The present invention provides a probe card for a micro-bump test, which is applied in a probe system for testing a device under test having a plurality of micro-bumps. The probe card includes a main circuit board, a space transformer, and a probe head as described above. The probe head and the main circuit board are disposed on two opposite sides of the space transformer. The tail portions of the probes of the probe head are electrically connected to the space transformer.

As a result, the probe card is applicable to the above-described testing method, and can attain the above-described effects. Such probe card is lowered in manufacturing difficulty, cost and the difficulty of being used on a machine for testing, can prevent the device under test from too complicated design, and can prevent the adjacent probes from collision with each other and the resulting short circuit or interference problem.

The present invention provides a probe system for a micro-bump test, which is configured to test a device under test having a plurality of micro-bumps. The probe system includes a chuck configured to support the device under test, a testing machine, and a probe card as described above. The probe card is electrically connected to the testing machine, and adapted to contact the device under test to make the testing machine electrically connected with the device under test for performing an electrical property testing process.

As a result, the probe system can be used to perform the above-described testing method to test the above-described device under test, and can attain the above-described effects.

The present invention provides a tested device. The tested device is a device which has been tested through an electrical property testing process. The electrical property testing process is performed by using the above-described testing method.

As a result, the tested device has been tested by the testing method having the above-described advantages and effects. The test results thereof have stable and great precision, which can ensure the tested device has good performance.

Further scope of applicability of the present invention will become apparent from the detailed description given hereinafter. However, it should be understood that the detailed description and specific examples, while indicating preferred embodiments of the invention, are given by way of illustration only, since various changes and modifications within the scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic view of a probe system for a micro-bump test and a wafer according to a first preferred embodiment of the present invention;

FIG. 2 and FIG. 3 are schematic sectional views of a probe head of a probe card of the probe system, showing the configurations adopting straight probes and buckling probes respectively;

FIG. 4 is a schematic perspective view showing a device under test on the wafer and the corresponding probes;

FIG. 5 is a schematic top view of the device under test;

FIG. 6 is a schematic front view of the device under test and the corresponding probes;

FIG. 7 is a schematic front view of a device under test and the corresponding probes according to a second preferred embodiment of the present invention;

FIG. 8 is a schematic top view of the device under test, also schematically showing the projected areas of the body portions and head portions of the associated first and second probes;

FIG. 9 is a schematic front view of a device under test and the corresponding probes according to a third preferred embodiment of the present invention;

FIG. 10 is a schematic top view of a device under test according to a fourth preferred embodiment of the present invention; and

FIG. 11 is a schematic front view of the device under test and the corresponding probes.

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

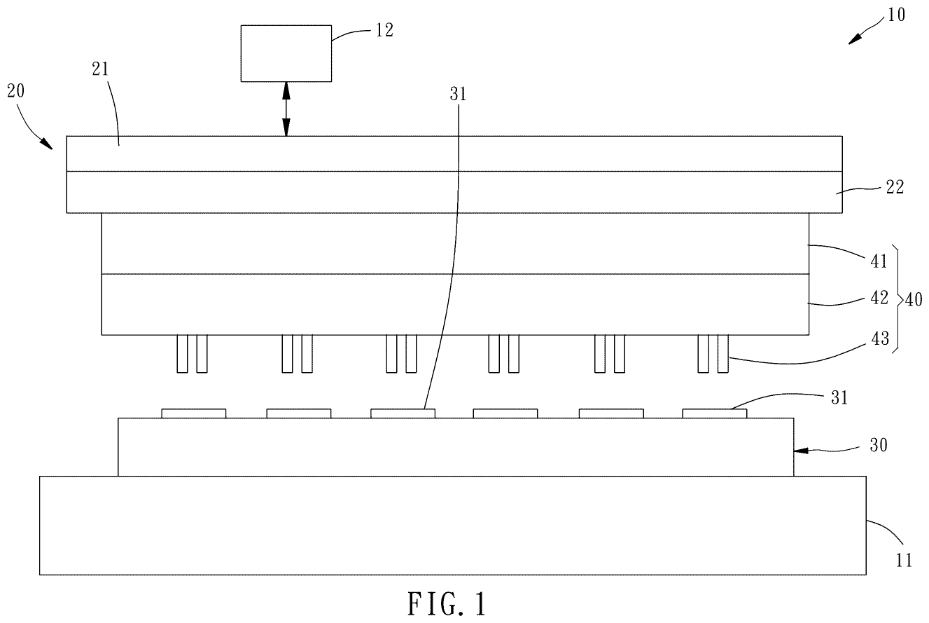

Referring to FIG. 1, a probe system 10 for a micro-bump test according to a first preferred embodiment of the present invention includes a chuck 11, a testing machine 12, and a probe card 20. A wafer 30 is placed on the chuck 11, and the wafer 30 is formed thereon with a plurality of devices under test 31. For the simplification of the figure and the convenience of illustration, FIG. 1 only schematically shows the devices under test 31, but doesn't show micro-bumps on the devices under test 31, which will be specified hereinafter.

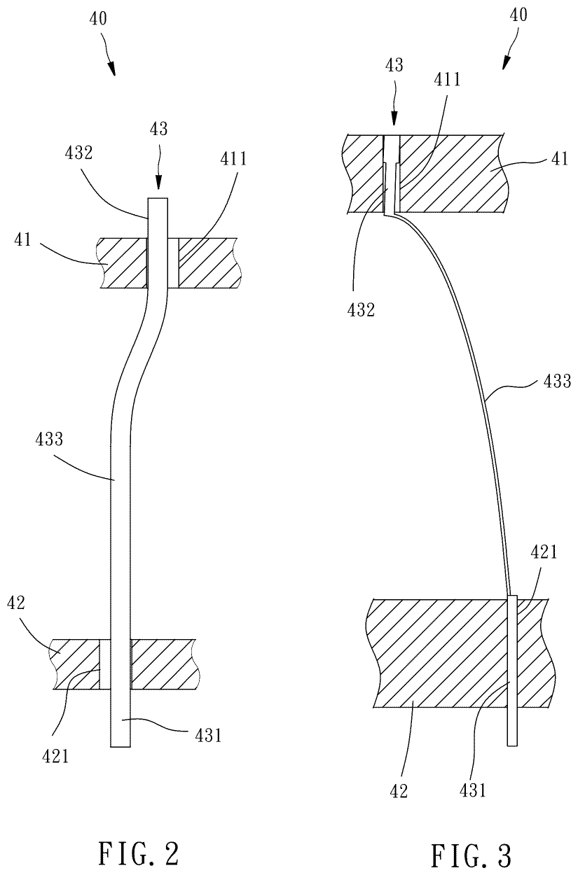

The probe card 20 includes a main circuit board 21, a space transformer 22, and a probe head 40. The main circuit board 21 and the probe head 40 are disposed on two opposite sides of the space transformer 22. The probe head 40 in this embodiment includes two guide units, i.e. an upper guide unit 41 and a lower guide unit 42, and a plurality of probes 43 inserted in the guide units. Referring to FIG. 2 and FIG. 3, the upper guide unit 41 includes a plurality of guiding holes 411. The lower guide unit 42 includes a plurality of guiding holes 421. The probe 43 is slidably inserted in the guiding holes 411, 421. For the simplification of the figures and the convenience of illustration, only one guiding hole 411, one guiding hole 421 and one probe 43 are shown in FIG. 2 and FIG. 3. In FIG. 2 and FIG. 3, two kinds of probes different in structural type are shown respectively, which are selectable for use according to different usage requirements, not both disposed in a same probe card 20 at the same time. The probe 43 includes a head portion 431 located at an end of the probe 43, a tail portion 432 located at the other end of the probe 43, and a body portion 433 located between the head portion 431 and the tail portion 432. The head portion 431 is inserted in the guiding hole 421 of the lower guide unit 42 for contacting the device under test 31. The tail portion 432 is inserted in the guiding hole 411 of the upper guide unit 41 for being abutted against a pad on the lower surface of the space transformer 22 and thereby electrically connected to the space transformer 22, so that the probe 43 is electrically connected to the testing machine 12 through the space transformer 22 and the main circuit board 21. As a result, when the head portions 431 of the probes 43 contact the micro-bumps of the device under test 31, the testing machine 12 is electrically connected with the device under test 31 through the probe card 20, such that an electrical property testing process can be performed for testing the electrical property of the device under test 31. The body portion 433 of the probe 43 is located between the upper and lower guide units 41, 42, and the body portion 433 is usually configured being able to slightly elastically deform when the probe 43 contacts the device under test 31, which will be specified hereinafter.

According to some embodiments of the present invention, such as those shown in FIG. 2 and FIG. 3, each probe 43 included in the probe head 40 may be the probe called buckling probe (or buckling beam) in this field. That is, the body portion 433 of the probe 43 may have constant transverse cross-sections among the overall length thereof. For example, the shape of the transverse cross-sections is a substantial rectangle, and preferably a square or a rectangle. The body portion 433 is adapted to curve and/or stretch substantially at the center thereof, so as to deform during the process of testing the device under test 31. However, in some other embodiments, the body portion 433 of each probe 43 is unnecessary to have constant transverse cross-sections among the overall length thereof.

In this specification, the term ‘substantial rectangle’ refers to the rectangular shape and other practical results that may be produced under the intention of manufacturing the body portion (or head portion) with rectangular transverse cross-sections, such as trapezoid. More specifically speaking, those skilled in the technical field of the present invention should understand that even though the equipment for manufacturing the probe 43 is assigned to manufacture the probe having rectangular transverse cross-sections, the transverse cross-sections of the actually produced probe 43 may still have a certain tolerance or manufacturing error so that in some embodiments the shape of the transverse cross-sections of the body portion 433 (or head portion 431) of the probe 43 is not the geometrically perfect rectangle. Nevertheless, the shape still has the same basic outline and features as a rectangle, and small rounded corners, chamfers, or manufacturing errors on any edge do not affect its functionality and effect of being considered rectangular in design. For example, if the four sides of the transverse cross-section are approximately straight lines and the included angles are close to right angles (e.g. 90±5 degrees), the shape may still be regarded as a ‘substantial rectangle’. In addition, as long as the shape can realize functions comparable to those of an ideal rectangle, such as guiding ability, contact stability, or arrangement density, it falls within the meaning of the ‘substantial rectangle’ as referred to in this specification. The term ‘guiding ability’ used herein refers to the capability of the probe, owing to its geometric shape, structural design, or assembly manner, to be restricted to a specific direction or path of movement or positioning during a testing process or installation operation. For example, a probe having rectangular transverse cross-sections may cooperate with a guide plate or a positioning structure to avoid rotation or displacement, thereby ensuring consistent probe alignment, stable contact, and improved overall alignment accuracy of a multi-probe array.

The applicable probes 43 for the present invention may at least include the straight probe as shown in FIG. 2 or the buckling probe (or called pre-curved probe) as shown in FIG. 3. The straight probe refers to the probe 43 shaped as a straight line when the manufacture thereof is accomplished. The body portion 433 thereof is curved by the transverse offset between the upper and lower guide units 41, 42 after the probe 43 is installed in the upper and lower guide units 41, 42. The buckling probe refers to the probe 43 which has the buckling shape when the manufacture thereof is accomplished. That means the body portion 433 thereof is originally curved in shape, so it doesn't need to be curved by the offset between the upper and lower guide units 41, 42. More specifically speaking, the straight probe may be, for example, a forming wire (also referred to as FW) or a microelectromechanical systems (MEMS) wire (also referred to as MW). The pre-curved probe may be, for example, a cobra probe or a MEMS body pre-curved forming probe, and so on.

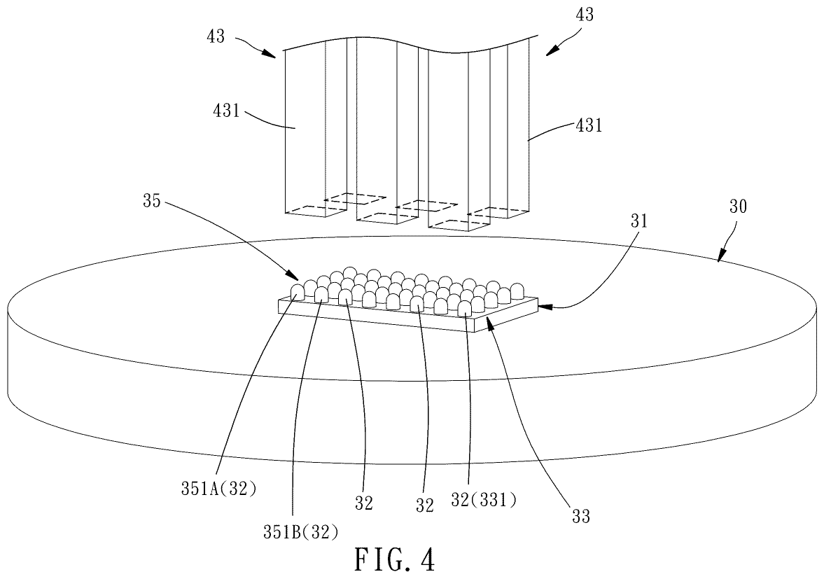

As shown in FIG. 4, the head portion 431 of each probe 43 is configured to be abutted against the micro-bumps (specified hereinafter) of the device under test 31 integrated in the semiconductor wafer 30. The head portions 431 of only six probes 43 are schematically shown in FIG. 4. When each probe 43 is applied with a load, such as the force received by the bottom end of each probe 43 contacting the corresponding micro-bumps during the device under test 31 being tested, the body portion 433 of each probe 43 can be deflected and deformed in an arc manner along its longitudinal extending axis. For the simplification of the figure and the convenience of illustration, only one of the devices under test 31 of the wafer 30 and its corresponding probes 43 are schematically shown in FIG. 4.

It should be mentioned here that when the probe 43 is in use to test the device under test 31, the head portion 431 of the probe 43 and the micro-bumps of the device under test 31 contact each other, and then relatively displace for a distance called overdrive (also referred to as OD) or called overtravel (also referred to as OT) to further approach each other. That makes the body portion 433 of the probe 43 compressed and deformed in a buckling manner, and makes the head portion 431 of the probe 43 pressed and contact the micro-bumps of the device under test 31. During this process, the force applied by the probe 43 to the micro-bumps of the device under test 31 is defined as the probe contact force in the present invention. The larger the probe contact force, the smaller the contact resistance between the probe 43 and the micro-bump of the device under test 31. The probe contact force is measured by applying the OD/OT to the probe 43 to deform the body portion 433 thereof in a buckling manner, and meanwhile measuring the value of the force applied by the probe 43 on a force sensor.

Further speaking, the probe contact force includes a probe deformation force and a probe friction. The probe deformation force refers to the force required for the elastic deformation of the probe 43 in the process of the aforementioned overdrive. The probe deformation force depends on many factors, such as the material properties of the probe 43 (e.g. Young's modulus, elastic modulus), the final geometric shape and size of the probe 43 (e.g. length, thickness, width, and so on). The probe friction refers to the friction applied to the probe 43 from the inner wall of the aforementioned guiding hole 411 of the upper guide unit 41 and/or the inner wall of the aforementioned guiding hole 421 of the lower guide unit 42. The probe contact force can steadily push the tail portion 432 of the probe 43 to be abutted against the pad of the aforementioned space transformer 22 (also referred to as ST), and then buckle the body portion 433 of the probe 43. That can make the probe 43 and the micro-bump of the device under test 31 electrically connected with each other, thereby making the micro-bump of the device under test 31 electrically connected to the testing machine through the probe 43.

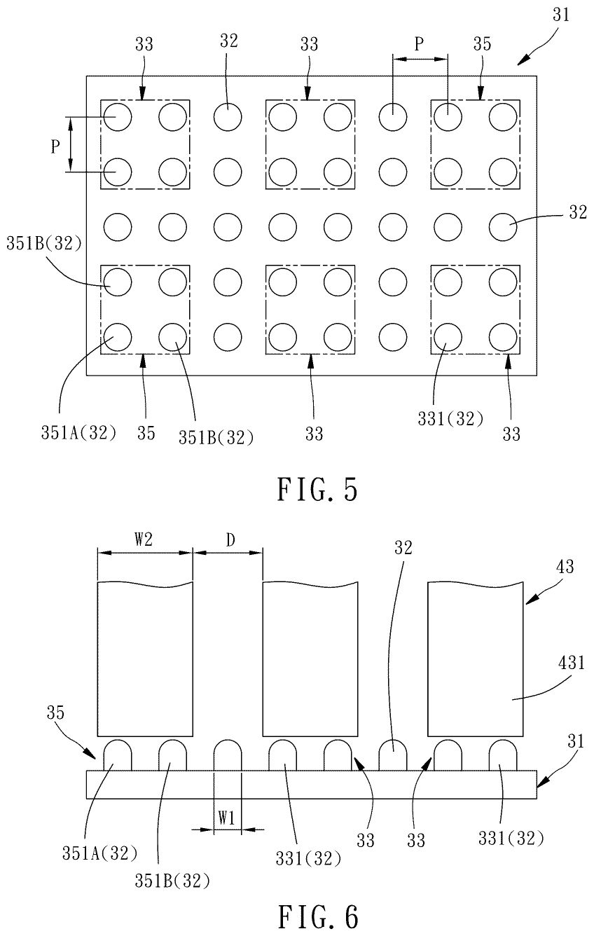

The testing method provided by the present invention will be described hereinafter, and the arrangement of the micro-bumps of the device under test 31 will be further described at the same time. Referring to FIG. 4 to FIG. 6, the testing method includes the following step a) to step d).
a) Provide the device under test 31. The device under test 31 has a die connecting surface, and a micro-bump array composed of a plurality of micro-bumps 32 on the die connecting surface. The width W1 of each micro-bump 32 is substantially smaller than 30 micrometers. The micro-bump array is defined with a plurality of bump units. In FIG. 5, the bump units are schematically demarcated by squares drawn with imaginary lines. The micro-bumps located in a same square belong to a same bump unit. The device under test 31 actually has a large number of micro-bumps 32, which may be more than 100 thousand. Each bump unit is preferable to include two to four micro-bumps 32. Therefore, the amount of the bump units is also quite large. For the simplification of the figures and the convenience of illustration, only six bump units are shown in the figures of the present invention, including four first bump units 33 and two second bump units 35. In this embodiment, each first bump unit 33 includes four micro-bumps 32 (also referred to as first micro-bumps 331 hereinafter) grouping together, which are arranged in a 2×2 array. The first micro-bumps 331 in the same first bump unit 33 are all arranged for transmitting a first signal. The first signal is one of a power signal and a ground signal.

Further speaking, the device under test 31 usually has a large number of power micro-bumps for transmitting the power signal and ground micro-bumps for transmitting the ground signal, which are all referred to as first micro-bumps 331 in the present invention. The first micro-bumps 331 in the same first bump unit 33 should have the same attribute. That is, the four first micro-bumps 331 are all power micro-bumps, or all ground micro-bumps. The power signal and the ground signal are both referred to as first signals in the present invention. For example, among the four first bump units 33 of the device under test 31 in this embodiment, two first bump units 33 may be arranged for transmitting the power signal, and the other two first bump units 33 are arranged for transmitting the ground signal.

In this embodiment, each second bump unit 35 also includes four micro-bumps 32 (also referred to as second micro-bumps hereinafter) grouping together, which are arranged in a 2×2 array. The micro-bumps 32 of each second bump unit 35 include at least one selected micro-bump 351A arranged for transmitting a second signal, and at least one dummy micro-bump 351B unable to transmit the second signal out of the second bump unit 35. The second signal is a test signal different from the power signal and the ground signal. In this embodiment, the four second micro-bumps 32 of each second bump unit 35 include only one selected micro-bump 351A, and the other three are all dummy micro-bumps 351B.

Further speaking, the device under test 31 usually has many testing micro-bumps for the input and output of test signals, which are the selected micro-bumps 351A in the present invention. In the testing method of this embodiment, the second bump unit 35 is arranged in a way that the dummy micro-bumps 351B are additionally provided near each testing micro-bump so that the amount of the micro-bumps of the second bump unit 35 is the same with the amount of the micro-bumps of the first bump unit 33. The amount can be any plural number, such as two, three, four or more. Because the testing micro-bumps are arranged for transmitting different test signals respectively, different second bump units 35 are arranged for transmitting different test signals respectively. The test signals are all referred to as second signals in the present invention.

It should be mentioned here that on the device under test 31 in the present invention, the first micro-bumps 331 and the second micro-bumps or the bump that will be mentioned hereinafter may have been formed on the wafer 30 when the manufacture of the wafer 30 is accomplished. Alternatively, a redistribution layer (also referred to as RDL) may be further formed on the surface of the wafer 30 after the manufacture of the wafer 30 is accomplished, and the first and second micro-bumps and/or bump are arranged on the redistribution layer.
b) Place the device under test 31 on the chuck 11 of the probe system 10, as shown in FIG. 1.
c) Provide the probe card 20. In the probe card 20 of the present invention, the interval D between the head portions 431 of at least two adjacent probes 43, or every two adjacent probes 43, is larger than or equal to the width W1 of one micro-bump 32, as shown in FIG. 6.
d) Test the device under test 31 by using the head portions 431 of the probes 43 of the probe card 20 to contact the bump units of the device under test 31, including the first and second bump units 33, 35, respectively.

In other words, the first and second bump units 33, 35 arranged on the device under test 31 are configured for all the micro-bumps 32 in a same bump unit to be contacted by a same probe 43, and each probe 43 only contacts a bump unit. In practice, the device under test 31 is arranged thereon with relatively more power micro-bumps and ground micro-bumps, and relatively fewer testing micro-bumps. Therefore, the power micro-bumps or ground micro-bumps are arranged as the above-described first bump unit 33 for a same probe 43 to contact a plurality of first micro-bumps 331 at the same time to provide the power signal or ground signal to the circuits respectively corresponding to the first micro-bumps 331.

As a result, the amount of the probes 43 for contacting the power micro-bumps and ground micro-bumps is much smaller than the amount of the power micro-bumps and ground micro-bumps. Therefore, the amount of the probes 43 disposed in the probe card 20 is highly reduced, and the probes 43 can be provided with relatively larger cross-sectional area and relatively larger pitch between the probes 43. That can lower the difficulty of manufacturing the probe card 20, the cost of the probe card 20, and the difficulty of using and maintaining the probe card 20, and the design of the device under test 31 is not too complicated. Besides, the interval D between the head portions 431 of at least two adjacent probes 43, or every two adjacent probes 43, is larger than or equal to the width W1 of one micro-bump 32, such that the adjacent probes 43 have a relatively larger space therebetween for mechanical operation. That prevents the adjacent probes 43 from collision with each other and the resulting short circuit or interference problem, so as to satisfy the testability and the reliability, improve the stability and test accuracy of the testing process, and improve the MTBF and service life of the probe card 20.

The probe card 20 actually adopting the arrangement provided by the present invention has at least 10000 probes 43. The width W2 of the head portion 431 of each probe 43 is substantially smaller than 100 micrometers. The interval D between the head portions 431 of the adjacent probes 43 is substantially larger than or equal to 20 micrometers. In this embodiment, there is at least one micro-bump 32 reserved between at least two adjacent bump units, or every two adjacent bump units, and not belonging to any bump unit. Therefore, for the probes 43 arranged correspondingly in position to the bump units respectively, there is a sufficient interval D between the head portions 431 of the adjacent probes 43. For example, if the width W1 of the micro-bump 32 is 20 micrometers and the pitch P between the micro-bumps 32 is 40 micrometers, the adjacent micro-bumps 32 only have an interval of 20 micrometers therebetween. If the head portion 431 of the probe 43 is configured with an area perfectly covering the four micro-bumps of a same bump unit, the width W2 of the head portion 431 of the probe 43 is 60 micrometers, such that the interval D between the head portions 431 of the adjacent probes 43 is about 60 micrometers and the pitch between the adjacent probes 43 can approximately attain 120 micrometers.

In another aspect about the second bump unit 35, because the testing micro-bumps should transmit different test signals respectively, a same probe 43 cannot contact a plurality of testing micro-bumps at the same time. In order to let the testing micro-bumps receive the same probing pressure with the first micro-bumps 331, the second bump unit 35 is arranged in a way that extra micro-bumps, i.e. dummy micro-bumps 315B, are additionally provided near the testing micro-bump actually for transmitting the test signal, i.e. the selected micro-bump 351A, for a same probe 43 to contact the selected micro-bump 351A and the dummy micro-bumps 351B at the same time to provide the test signal to the circuit corresponding to the selected micro-bump 351A. In this way, the dummy micro-bumps 351B bear a part of the probe contact force, so that the probing pressure received by the selected micro-bump 351A can be the same with the probing pressure received by the first micro-bump 331. It can be seen that the primary function of the dummy micro-bump 351B is to share the probe contact force with the selected micro-bump 351A, so the dummy micro-bump 351B and the selected micro-bump 351A may be electrically disconnected from each other. In this way, the dummy micro-bump 351B needs not to connect any circuit, which makes the device under test 31 have relatively fewer circuits and thereby relatively easier to design and manufacture. The dummy micro-bump 351B may be substantially the same in size with the selected micro-bump 351A, so that the micro-bumps on the device under test 31 are uniform in size, thereby relatively simpler to design, facilitating the positional arrangement of the micro-bumps, and sharing the probe contact force relatively more evenly, which is beneficial for generating consistent probing performance. Besides, in another embodiment, the second bump unit 35 is arranged in a way that the dummy micro-bump 351B and the selected micro-bump 351A are electrically connected with each other. For example, they may be electrically connected with each other through a trace. In this way, the dummy micro-bump 351B not only bears a part of the probe contact force, but also receives the test signal transmitted from the probe 43. However, the dummy micro-bump 351B is arranged being unable to transmit the test signal out of its belonging second bump unit 35. Therefore, the dummy micro-bump 351B can only transmit the test signal to the selected micro-bump 351A of its belonging second bump unit 35, and then the test signal is transmitted through the selected micro-bump 351A out of its belonging second bump unit 35. That can improve the test signal transmitting stability of the second bump unit 35.

However, the second bump unit 35 in the present invention is unlimited to the arrangement provided in this embodiment. For example, the second bump unit 35 may be not provided with the dummy micro-bump 351B, but provided with a relatively larger bump to replace the selected micro-bump 351A, i.e. the testing micro-bump, so as to make the probing pressure received by the bump the same with the probing pressure received by the first micro-bump 331.

In other words, the arrangement with the dummy micro-bump 351B and the arrangement of replacing the testing micro-bump by a relatively larger bump are both using the same probes 43, i.e. not using hybrid probes, to provide the same contact force to the same number of micro-bumps 32 or a single relatively larger bump with approximately equal area to the total area of the aforementioned same number of micro-bumps 32, so that each micro-bump 32 or bump receives the same probing pressure. That can avoid the poor probe planarity problem that may be caused by difference in wear loss between the probes of different probe types. Because the body portion 433 makes up a large proportion of the probe 43 in length, the body portion 433 has relatively larger affection on the probe contact force. Therefore, in order to make the probes 43 generate approximately equal contact force, the present invention only confines the body portions 433 of the probes 43 to be substantially the same in size. That means the body portions 433 of the probes 43 are substantially the same in structural type, and/or substantially the same in length, width and thickness, and/or substantially the same in cross-sectional area. For example, the probes 43 adopted in this embodiment are substantially the same at least in body portions 433 thereof in all the aspects of structural type, length, width, thickness, and cross-sectional area. In this way, the probes 43 generate substantially the same probe contact force and wear loss. In another embodiment, the probes 43 adopted in the probe card 20 may be all the same. For example, all the probes 43 are substantially the same in structural type, length, width, thickness, and cross-sectional area. In the embodiment shown in FIG. 4 and FIG. 6, the head portions 431 of the probes 43 are all the same, the same in cross-sectional area and the same in cross-sectional shape, wherein the cross-sectional shape may be a circle or a rectangle.

However, the present invention may use hybrid probes. That is, the probe type of the probe 43 for contacting the second bump unit 35 may be different from the probe type of the probe 43 for contacting the first bump unit 33, such as those in the following two embodiments.

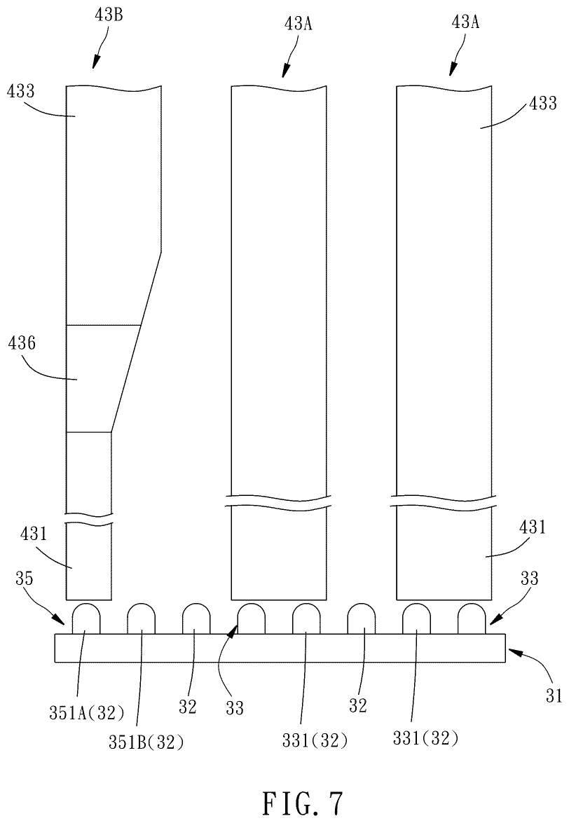

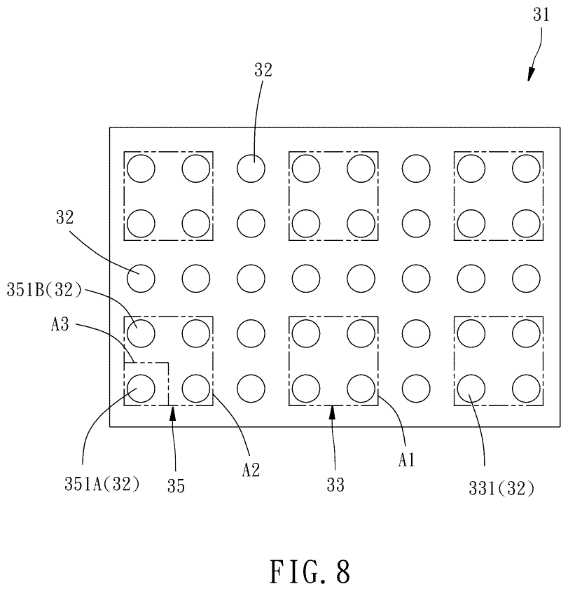

Referring to FIG. 7 and FIG. 8, a second preferred embodiment of the present invention provides another probe arrangement. The device under test 31 in this embodiment is the same with that shown in FIG. 5. The plurality of probes in this embodiment have the same tail portions 432 and the same body portions 433, but have differently sized head portions 431.

Specifically speaking, the probes in this embodiment include four first probes 43A for contacting the first bump units 33 respectively, and two second probes 43B for contacting the second bump units 35 respectively. The body portion 433 and the head portion 431 of the first probe 43A are the same in cross-sectional area, and the cross-sectional area thereof equals to the projected area A1 of the head portion 431. The cross-sectional area of the second probe 43B gradually reduce from the body portion 433 to the head portion 431 through a gradually narrowing portion 436, so that the cross-sectional area of the body portion 433 of the second probe 43B, which equals to the projected area A2 of the body portion 433, is larger than the cross-sectional area of the head portion 431, which equals to the projected area A3 of the head portion 431. It can be seen in FIG. 7 and FIG. 8 that the body portions 433 of the first and second probes 43A, 43B and the head portion 431 of the first probe 43A are all the same in cross-sectional area, and their projected areas A1, A2 each cover four micro-bumps 32. However, the head portion 431 of the second probe 43B has relatively smaller cross-sectional area, and the projected area A3 thereof covers only one micro-bump 32. During the device under test being tested, the head portion 431 of the first probe 43A contacts all the first micro-bumps 331 of the first bump unit 33 at the same time, and the head portion 431 of the second probe 43B contacts only one second micro-bump, i.e. the selected micro-bump 351A.

In other words, the probes in the present invention, under the condition that the body portions 433 thereof are substantially the same in size, may still have differently sized head portions 431, and the first and second probes 43A, 43B can still generate substantially the same probe contact force. Besides, even though the head portions 431 of the first and second probes 43A, 43B contact different amounts of micro-bumps 32, the second bump unit 35 can be still arranged in a way that the micro-bumps 32 thereof are all included in the projected area A2 of the body portion 433 of the second probe 43B, so that the projected areas A1, A2 of the body portions 433 of the first and second probes 43A, 43B still correspond to the same amount of micro-bumps 32. Therefore, the arrangement of the micro-bumps 32 of the second bump unit 35 can be the same with the arrangement of the micro-bumps 32 of the first bump unit 33, such that the micro-bumps 32 of the device under test 31 still maintain a neat arrangement, such as being arranged in a matrix. In this way, the design of the micro-bumps of the device under test 31 is simple and uniform.

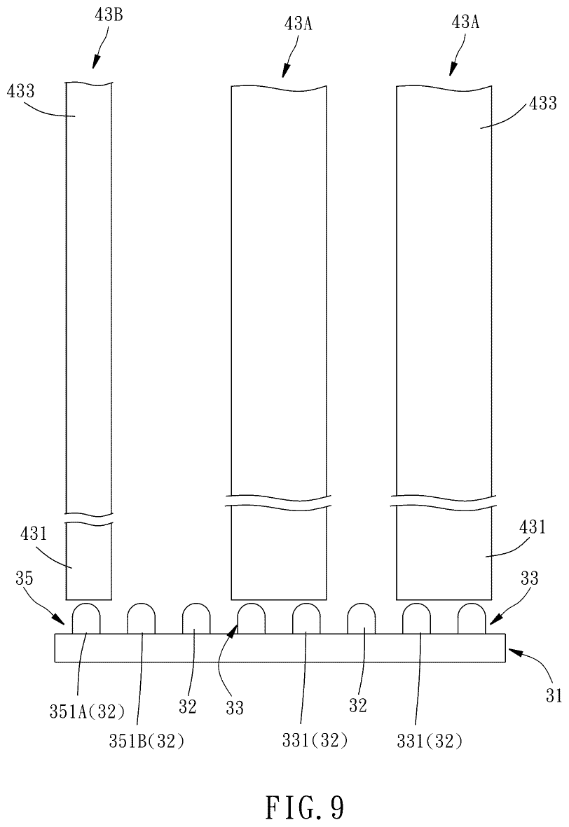

Alternatively, the probes in the present invention are unlimited to satisfy the condition that the body portions 433 are substantially the same in size, such as those in a third preferred embodiment of the present invention shown in FIG. 9. The third preferred embodiment is different from the second preferred embodiment in that the body portion 433 and the head portion 431 of the second probe 43B in this embodiment are the same in cross-sectional area, and the cross-sectional area thereof covers only one micro-bump 32. In other words, in this embodiment the first probe 43A is entirely relatively thicker and arranged to contact a plurality of power micro-bumps or ground micro-bumps, i.e. the plurality of first micro-bumps 331 of the first bump unit 33, at the same time. The second probe 43B is entirely relatively thinner and arranged to contact only one testing micro-bump, i.e. the selected micro-bump 351A of the second bump unit 35. In the probe arrangements provided in the second and third preferred embodiments, the second bump unit 35 may only have the selected micro-bump 351A, i.e. the testing micro-bump, but have no dummy micro-bump 351B. At the positions of the dummy micro-bumps 351B shown in the figures, there may be no micro-bump, or there may be power micro-bumps or ground micro-bumps.

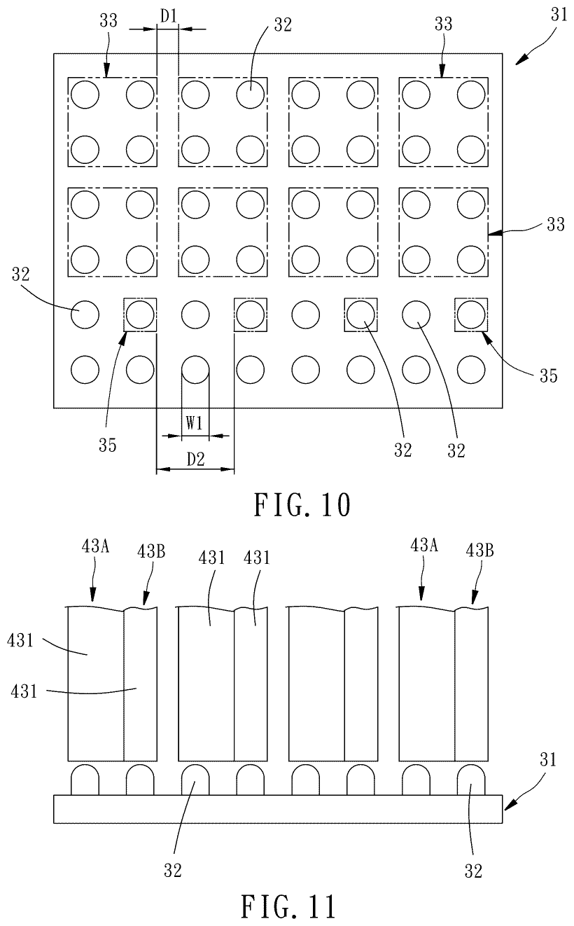

The present invention is unlimited to that the intervals D between the head portions 431 of all the probes 43 are all larger than or equal to the width W1 of one micro-bump 32. According to the usage requirements, there may be only a part of the probes 43 arranged with the interval D larger than or equal to the width W1 of one micro-bump 32. An example of that is a fourth preferred embodiment of the present invention shown in FIG. 10 and FIG. 11 and specified hereinafter.

In this embodiment, the micro-bumps on the device under test 31 are arranged in a way that there are eight first bump units 33 directly adjacent to each other, which means there is no micro-bump 32 between the adjacent first bump units 33. Besides, there are four second bump units 35 indirectly adjacent to each other, which means there is a micro-bump 32 between the adjacent second bump units 35, not belonging to any bump unit, and not going to be contacted by any probe. The amount of the micro-bumps 32 of the second bump unit 35, which is one in this embodiment, is smaller than the amount of the micro-bumps 32 of the first bump unit 33, which is four in this embodiment. Corresponding to the above-described micro-bump arrangement, the probes in this embodiment are arranged in a way that there are eight adjacent first probes 43A and four adjacent second probes 43B. The first probes 43A are arranged for contacting the first bump units 33 respectively. The second probes 43B are arranged for contacting the second bump units 35 respectively. The interval between the head portions 431 of the adjacent first probes 43A, which equals to the interval D1 between the first bump units 33 shown in FIG. 10, is smaller than the width W1 of one micro-bump 32. The interval between the head portions 431 of the adjacent second probes 43B, which equals to the interval D2 between the second bump units 35 shown in FIG. 10, is larger than or equal to the width W1 of one micro-bump 32.

In other words, in this embodiment each of the first probes 43A for transmitting the power signal and the ground signal is arranged for contacting four micro-bumps 32 at the same time, and the adjacent first probes 43A are not spaced from each other for at least the width W1 of one micro-bump 32. Each second probe 43B for transmitting the test signal is arranged for contacting only one micro-bump 32, so the second probe 43B is thinner than the first probe 43A. In this way, in the condition that the micro-bumps 32 maintain the neat arrangement and the first and second probes 43A, 43B also have a neat arrangement, the adjacent second probes 43B can be still spaced from each other for at least the width W1 of one micro-bump 32. As a result, this embodiment can also realize that the probe card has relatively fewer probes and a part of the probes have a relatively larger pitch therebetween, and therefore can also lower the difficulty of manufacturing the probe card, the cost of the probe card and the difficulty of using the probe card on the machine for testing, and can prevent the device under test from too complicated design, and can prevent the adjacent probes from collision with each other and the resulting short circuit or interference problem.

In conclusion, the present invention provides a testing method, a probe head 40, a probe card 20 and a probe system 10 for a micro-bump test to test the device under test 31 with the micro-bumps 32 arranged for at least a part of the probes 43 of the probe card 20 to contact a plurality of micro-bumps 32, and the interval D between the head portions 431 of the adjacent probes 43 is larger than or equal to the width W1 of one micro-bump 32. As a result, the probe card 20 can be arranged with relatively fewer probes 43, and the probes 43 can be provided therebetween with relatively larger pitch. Therefore, the difficulty of manufacturing the probe card 20, the cost of the probe card 20 and the difficulty of using the probe card 20 on the machine for testing are relatively lower, and the design of the device under test 31 is not too complicated. In addition, the adjacent probes have a relatively larger interval therebetween for mechanical operation. That can prevent the adjacent probes from collision with each other and the resulting short circuit or interference problem.

The invention being thus described, it will be obvious that the same may be varied in many ways. Such variations are not to be regarded as a departure from the scope of the invention, and all such modifications as would be obvious to one skilled in the art are intended to be included within the scope of the following claims.

As used herein, when the term ‘substantially’ modifies a degree or relationship, it not only includes the stated degree or relationship, but also includes the entire range of the stated degree or relationship. A substantial quantity of a stated degree or relationship may include at least 95% of the stated degree or relationship. For example, in this specification, the phrase ‘substantially the same in size’ refers to that the body portions 433 of the probes 43 are exactly the same in size, or their sizes have a difference but the difference is within an allowable manufacturing or design tolerance range, and does not substantially affect the function, performance, or intended equivalence of the probes in the micro-bump test. For example, when the difference in length, width, thickness, cross-sectional area, or diameter of the body portion is within ±5% and does not affect the testing effect, it is still regarded as being ‘substantially the same in size’, unless otherwise specifically defined.

In this specification, the phrase ‘the interval D is substantially larger than or equal to 20 micrometers’ refers to that the minimum distance between at least two adjacent head portions 431 is 20 micrometers, or slightly less than 20 micrometers but still within an acceptable manufacturing or design error range, and does not affect the technical objectives of electrical insulation, contact reliability, or arrangement density of the probes. For example, when the interval is above 19 micrometers and provides a sufficient dielectric gap to prevent electrical interference, it is still regarded as being ‘substantially larger than or equal to 20 micrometers.’ In addition, the expression ‘substantially larger than or equal to’ also encompasses the value of 20 micrometers itself and any range above it, unless otherwise specifically limited by the context.

What is claimed is:

1. A testing method for a micro-bump test, which uses a probe card in a probe system to test a device under test having a plurality of micro-bumps, the testing method comprising the steps of:
providing the device under test, the device under test comprising a plurality of bump units, the bump units comprising at least one first bump unit and at least one second bump unit, the first bump unit comprising a plurality of said micro-bumps grouping together, the micro-bumps of the same first bump unit being all arranged for transmitting a first signal, the first signal being one of a power signal and a ground signal, the second bump unit being arranged for transmitting a second signal, the second signal being a test signal different from the power signal and the ground signal;
placing the device under test on a chuck of the probe system;
providing the probe card, the probe card comprising a plurality of probes, each of the probes comprising a head portion located at an end of the probe for contacting the device under test, a tail portion located at the other end of the probe, and a body portion located between the head portion and the tail portion, an interval between the head portions of at least two adjacent said probes being larger than or equal to a width of one said micro-bump; and
testing the device under test by using the head portions of the probes of the probe card to contact the bump units of the device under test, respectively.

2. The testing method as claimed in claim 1, wherein the second bump unit comprises a plurality of said micro-bumps grouping together; an amount of the micro-bumps of the second bump unit is the same with an amount of the micro-bumps of the first bump unit; the micro-bumps of the second bump unit comprise at least one selected micro-bump arranged for transmitting the second signal, and at least one dummy micro-bump unable to transmit the second signal out of the second bump unit.

3. The testing method as claimed in claim 2, wherein the first bump unit comprises two to four said micro-bumps grouping together; the second bump unit comprises one said selected micro-bump and one to three said dummy micro-bumps, which group together.

4. The testing method as claimed in claim 1, wherein the body portions of the probes are substantially the same in size.

5. The testing method as claimed in claim 1, wherein the width of each of the micro-bumps is substantially smaller than 30 micrometers; an amount of the probes of the probe card is at least 10000; a width of the head portion of each of the probes is substantially smaller than 100 micrometers; a cross-sectional shape of the head portion of each of the probes is a substantial rectangle.

6. The testing method as claimed in claim 1, wherein at least two adjacent said bump units are provided therebetween with at least one said micro-bump.

7. The testing method as claimed in claim 1, wherein the interval between the head portions of at least two adjacent said probes is substantially larger than or equal to 20 micrometers.

8. The testing method as claimed in claim 1, wherein the bump units comprise a plurality of said first bump units and a plurality of said second bump units; the probes comprise a plurality of first probes and a plurality of second probes; the first probes are arranged for contacting the first bump units, respectively; the second probes are arranged for contacting the second bump units, respectively; the interval between the head portions of the adjacent first probes is smaller than the width of one said micro-bump; the interval between the head portions of the adjacent second probes is larger than or equal to the width of one said micro-bump.

9. The testing method as claimed in claim 1, wherein the bump units comprise a plurality of said first bump units and a plurality of said second bump units; there is no said micro-bump between the adjacent first bump units; there is at least one said micro-bump between the adjacent second bump units; each of the second bump units comprises at least one micro-bump with an amount smaller than an amount of the micro-bumps of each of the first bump units.

10. A probe head for a micro-bump test, which is comprised in a probe card for testing a device under test having a plurality of micro-bumps; the probe head comprising:
a guide unit comprising a plurality of guiding holes; and
a plurality of probes inserted through the guiding holes respectively, each of the probes comprising a head portion located at an end of the probe for contacting the device under test, a tail portion located at the other end of the probe, and a body portion located between the head portion and the tail portion;
wherein the head portions of the probes are arranged for contacting a plurality of bump units of the device under test, respectively; the bump units comprise at least one first bump unit and at least one second bump unit; the first bump unit comprises a plurality of said micro-bumps grouping together; the micro-bumps of the same first bump unit are all arranged for transmitting a first signal; the first signal is one of a power signal and a ground signal; the second bump unit is arranged for transmitting a second signal; the second signal is a test signal different from the power signal and the ground signal; an interval between the head portions of at least two adjacent said probes is larger than or equal to a width of one said micro-bump.

11. The probe head as claimed in claim 10, wherein the second bump unit of the device under test comprises a plurality of said micro-bumps grouping together; an amount of the micro-bumps of the second bump unit is the same with an amount of the micro-bumps of the first bump unit; the micro-bumps of the second bump unit comprise at least one selected micro-bump arranged for transmitting the second signal, and at least one dummy micro-bump unable to transmit the second signal out of the second bump unit.

12. The probe head as claimed in claim 11, wherein the first bump unit comprises two to four said micro-bumps grouping together; the second bump unit comprises one said selected micro-bump and one to three said dummy micro-bumps, which group together.

13. The probe head as claimed in claim 10, wherein the body portions of the probes are substantially the same in size.

14. The probe head as claimed in claim 10, wherein the width of each of the micro-bumps is substantially smaller than 30 micrometers; an amount of the probes of the probe head is at least 10000; a width of the head portion of each of the probes is substantially smaller than 100 micrometers; a cross-sectional shape of the head portion of each of the probes is a substantial rectangle.

15. The probe head as claimed in claim 10, wherein at least two adjacent said bump units are provided therebetween with at least one said micro-bump.

16. The probe head as claimed in claim 10, wherein the interval between the head portions of at least two adjacent said probes is substantially larger than or equal to 20 micrometers.

17. The probe head as claimed in claim 10, wherein the bump units comprise a plurality of said first bump units and a plurality of said second bump units; the probes comprise a plurality of first probes and a plurality of second probes; the first probes are arranged for contacting the first bump units, respectively; the second probes are arranged for contacting the second bump units, respectively; the interval between the head portions of the adjacent first probes is smaller than the width of one said micro-bump; the interval between the head portions of the adjacent second probes is larger than or equal to the width of one said micro-bump.

18. The probe head as claimed in claim 10, wherein the bump units comprise a plurality of said first bump units and a plurality of said second bump units; there is no said micro-bump between the adjacent first bump units; there is at least one said micro-bump between the adjacent second bump units; each of the second bump units comprises at least one micro-bump with an amount smaller than an amount of the micro-bumps of each of the first bump units.

19. A probe card for a micro-bump test, which is applied in a probe system for testing a device under test having a plurality of micro-bumps; the probe card comprising:
a main circuit board;
a space transformer; and
the probe head as claimed in claim 10, the probe head and the main circuit board being disposed on two opposite sides of the space transformer, the tail portions of the probes of the probe head being electrically connected to the space transformer.

20. A probe system for a micro-bump test, which is configured to test a device under test having a plurality of micro-bumps, the probe system comprising:
a chuck configured to support the device under test;
a testing machine; and
the probe card as claimed in claim 19, the probe card being electrically connected to the testing machine, and adapted to contact the device under test to make the testing machine electrically connected with the device under test for performing an electrical property testing process.

21. A tested device, the tested device being a device which has been tested through an electrical property testing process, the electrical property testing process being performed by using the testing method as claimed in claim 1.
